(19) United States
(12) Patent Application Publication
(10) Pub. No.: US 2016/0018635 A1
(43) Pub. Date: Jan. 21, 2016

(54) DISPLAY DEVICE

(71) Applicant: PIXTRONIX, INC., San Diego,, CA (US)

(72) Inventor: Masaya Adachi, Mobara City (JP)

(73) Assignee: PIXTRONIX, INC., San Diego,, CA (US)

(21) Appl. No.: 14/774,056

(22) PCT Filed: Mar. 14, 2014
(86) PCT No.: PCT/US2014/028262

§ 371 Date: Sep. 9, 2015

(30) Foreign Application Priority Data
Mar. 14, 2013 (JP) 2013-052403

(51) Int. Cl. G02B 26/02; G02B 5/04; B81B 7/02; G02B 5/00

(52) U.S. Cl. CPC G02B 26/02; G02B 5/005; G02B 5/045; B81B 7/02; B81B 2201/045

(57) ABSTRACT

[Problem] To provide a display device with a more uniform and wider view angle not dependent upon orientation.

[Resolution Means] A display device equipped with a backlight for emitting a planar light; a first aperture layer (225) whose first aperture allows light from the backlight to pass therethrough; a mechanical shutter (228) electrically driven by a thin-film transistor, that controls a transmission of light that passes through the first aperture layer; a second aperture layer (212) whose second aperture that corresponds to the first aperture in the first aperture layer allows light that passes through the mechanical shutter to pass therethrough; and a high refractive index layer (214) that covers a second aperture of the second aperture layer, that is a transparent layer with a higher refractive index than a transparent fluid (221) filling a space between the first aperture layer and the second aperture layer; a thickness of the high refractive index layer in a central portion of the second aperture is formed to be less than a thickness of the high refractive index layer at edge portions of the second aperture.

### RELATED APPLICATIONS

The present application for patent claims priority to Japanese Application No. 2013-052403, entitled “Display Device,” filed Mar. 14, 2013, and assigned to the assignee hereof and hereby expressly incorporated by reference herein.

### TECHNICAL FIELD

The present invention relates to a display device and more particularly to a display device that uses a microelectromechanical system in a pixel.

### BACKGROUND TECHNOLOGY

Flat panel display devices are frequently used in telecommunication terminals, television sets, and the like. Liquid-crystal display devices, which are one of these kinds of display devices, are used in many terminals. Liquid-crystal display devices are display devices that display an image by changing a degree of transmission of light irradiated from a backlight through a liquid-crystal panel by changing an orientation of liquid-crystal molecules sealed between two substrates of the liquid-crystal panel.

Meanwhile, structures that use micro-fabrication techniques known as microelectromechanical systems (MEMS) are used in various fields and are gaining attention in the field of display devices. Patent Document 1 describes a display device that displays an image by adjusting brightness by transmitting or blocking light from a backlight that passes through an aperture, by moving a shutter in a shutter mechanism that incorporates a MEMS shutter mechanism in each pixel.

Patent Document 2 describes arranging a plurality of apertures in a two-dimensional plane as a geometrically symmetrical pattern in a display device that includes a MEMS shutter in order to unify a view angle.

### RELATED ART DOCUMENTS

### Patent Documents

[Patent Document 1] Japanese Unexamined Patent Application Publication No. 2008-197668

[Patent Document 2] Japanese Unexamined Patent Application Publication No. 2011-209689

### SUMMARY OF THE INVENTION

### Problems to be Solved by the Invention

A movement distance of the MEMS shutter is small compared to a pixel size. For that reason, in order to increase transmittance of the MEMS panel, it is desired that a shape of the aperture (opening) be an anistropic shape having a short length in a direction parallel to a movement direction of the MEMS shutter and a long length in a direction orthogonal thereto. More specifically, it is desired that the shape of the aperture is rectangular with the direction parallel to the movement direction of the MEMS shutter being a short side, and that a plurality thereof is disposed. Note that in the present specification, when describing the shape of the aperture, the direction parallel to the movement direction of the MEMS shutter and in which the length is short will be referred to as a short axis direction and the direction orthogonal thereto will be referred to as a long axis direction. When the shape of the aperture is made to be anisotropic in this manner, there is a problem where the view angle becomes narrow in the short axis direction of the aperture. In other words, compared to a brightness when observing obliquely in an orientation parallel to the long axis direction of the aperture, a brightness when observing in an orientation parallel to the short axis direction is lower, and the view angle is narrower. That is, an orientation dependency occurs in the view angle. In Patent Document 2, unification of the view angle is attempted, but because it is difficult to dispose shutters with different operation directions in the same pixel without lowering an aperture ratio, and because pixels with different brightness are alternately lined up when observing obliquely, there is a concern that this is unpleasant to the observer.

The present invention is made in view of conditions described above, and an object thereof is to provide a display device that performs display control by a MEMS shutter where a view angle in an orientation parallel to a short axis direction of an aperture is wider and an orientation dependency of the view angle is thereby smaller.

### Means for Solving the Problems

The display device of the present invention is a display device provided with a backlight that emits a planar light and a display panel that displays an image by controlling light emitted from the backlight using a microelectromechanical system shutter (MEMS shutter) provided in each pixel, wherein one pixel has a first aperture layer having at least one opening with an anisotropic shape whose length in a direction substantially parallel to a movement direction of the MEMS shutter is short and whose length in a direction orthogonal thereto is long and a second aperture layer provided with at least one opening, which is disposed to correspond to the opening of the first aperture layer, with an anisotropic shape whose length in the direction substantially parallel to the movement direction of the MEMS shutter is short and whose length in the direction orthogonal thereto is long; in the one pixel, the MEMS shutter is provided between the first aperture layer and the second aperture layer and controls (switches) transmission and blocking of light passing through the first aperture layer by being electrically driven by a switching element; a space between the first aperture layer and the second aperture layer in which the MEMS shutter is provided is filled with a transparent fluid; a high refractive index layer, which is a transparent layer having a higher refractive index than the transparent fluid, is provided in the opening of the second aperture layer; and a thickness of the high refractive index layer in a central portion of the opening of the second aperture layer is less than a thickness at an edge portion of the opening of the second aperture layer.

Furthermore, in the display device of the present invention, the openings in the first aperture layer and the second aperture layer may both be rectangular and may be disposed in plurality.

Furthermore, in the display device of the present invention, the high refractive index layer may be configured of a first high refractive index layer configured of an organic material formed on the second aperture layer and a second high refractive index layer configured of an inorganic material formed on the first high refractive index layer.

Furthermore, in the display device of the present invention, the high refractive index layer may be formed of a material selected from among silicon oxide, titanium oxide, niobium oxide, or silicon nitride.

Furthermore, in the display device of the present invention, a half-value angle in the short axis direction may be smaller than the half-value angle of the long axis direction for the intensity of light emitted from the backlight.

Furthermore, in the display device of the present invention, the backlight may have a prism sheet having a ridge line that extends in the long axis direction of the openings of the first and the second aperture layers.

### BRIEF DESCRIPTION OF DRAWINGS

FIG. 1 is a diagram illustrating a MEMS shutter display device, according to a display device of a first embodiment of the present invention, that controls a displayed image using a shutter mechanism in each pixel.

FIG. 2 is a diagram illustrating a control configuration of a MEMS panel in FIG. 1.

FIG. 3 is a cross-sectional view for explaining a closed state of a shutter in the MEMS shutter display device.

FIG. 4 is a cross-sectional view for explaining an opened state of the shutter in the MEMS shutter display device.

FIG. 5 is a perspective view that extracts and illustrates three layers that control transmission of light from a backlight in one pixel of the MEMS panel.

FIG. 6 is a schematic plan view illustrating from a view from a front face of a display surface an arrangement of each aperture of a first aperture layer and a second aperture layer in one pixel of the MEMS panel.

FIG. 7 is a schematic cross-sectional view near the aperture of the second aperture layer.

FIG. 8 is a schematic cross-sectional view of a high refractive index layer that is an alternative example of a high refractive index layer in FIG. 7 illustrated with a view in the same way as in FIG. 7.

FIG. 9 is an exploded perspective view schematically illustrating a constitution of the MEMS panel and backlight.

FIG. 10 is a plan view schematically illustrating a constitution of the backlight in the first embodiment.

FIG. 11 is a schematic cross-sectional view illustrating one example of a cross-sectional shape of a light-guiding plate in FIG. 9.

FIG. 12 is a schematic cross-sectional view illustrating one example of a configuration of a prism sheet in the backlight in FIG. 9.

FIG. 13 is a graph showing one example of a relationship (brightness view angle characteristics) of brightness of the backlight and the view angle.

FIG. 14 is a view to describe a status of light when the shutter is open, illustrating a schematic cross-sectional structure of the MEMS panel.

FIG. 15 is a view to describe a status of light when the shutter is closed, illustrating a schematic cross-sectional structure of the MEMS panel.

FIG. 16 is an exploded perspective view schematically illustrating the MEMS panel and the backlight in a MEMS shutter display device, pursuant to a display device of a second embodiment of the present invention.

FIG. 17 is a schematic section illustrating a schematic configuration of a prism sheet in the backlight in FIG. 16.

FIG. 18 is an exploded perspective view schematically illustrating a constitution of the MEMS panel and backlight in a MEMS shutter display device, pursuant to a display device of a third embodiment of the present invention.

FIG. 19 is a schematic cross-sectional view illustrating one example of a cross-sectional configuration of a light-guiding plate of a backlight.

FIG. 20 is a schematic cross-sectional view illustrating one example of a configuration of a prism sheet in the backlight in FIG. 18.

### MODE FOR CARRYING OUT THE INVENTION

Embodiments of the present invention will now be described below with reference to the drawings. Note that the same symbols are applied to the same or similar elements in the drawings. Repeated explanations thereof will be omitted.

### First Embodiment

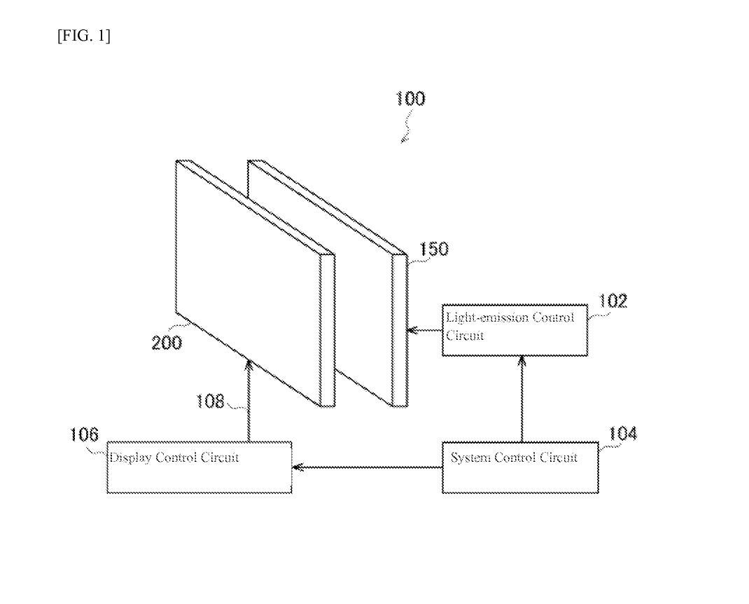

FIG. 1 is a diagram illustrating a MEMS shutter display device 100, according to a display device of a first embodiment of the present invention that controls a displayed image using a shutter mechanism in each pixel. As illustrated in FIG. 1, the MEMS shutter display device 100 includes a backlight 150, a MEMS panel 200 that controls a transmission of light from the backlight 150 using a MEMS shutter 228 (described in detail below), a light-emission control circuit 102 that controls light-emission operation of a light source of the backlight 150, a display-control circuit 106 that controls operation of the MEMS shutter 228 in the MEMS panel 200, and a system-control circuit 104 that implements comprehensive control of the light-emission control circuit 102 and the display-control circuit 106.

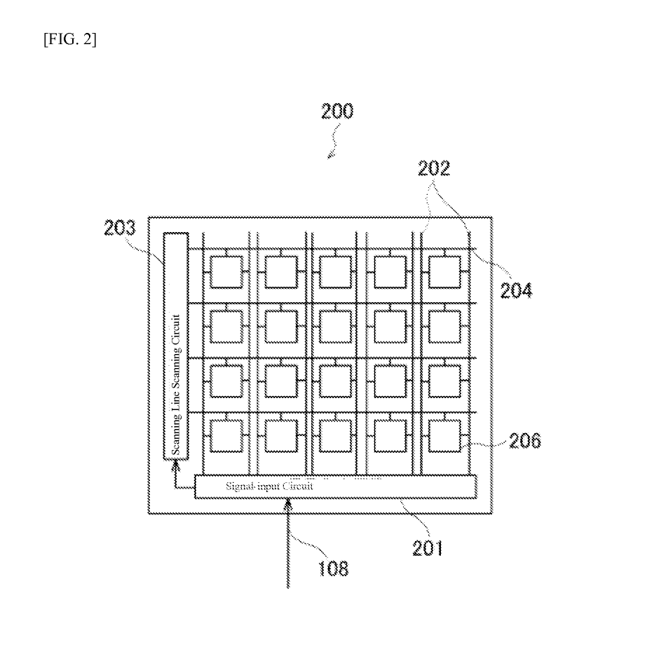

FIG. 2 is a diagram illustrating a control configuration of the MEMS panel 200 in FIG. 1. A pixel 206 is arranged in a matrix in a display region of the MEMS panel 200. A scanning-signal line 204 is connected in a line direction, and a signal line 202 is connected in a row direction on the pixel 206. A scanning-signal line-drive circuit 203 is connected to one end of the scanning-signal line 204. A signal-input circuit 201 is disposed at one end of the signal line 202. A panel-control line 108 is inputted to the signal-input circuit 201; the signal-input circuit 201 controls the scanning-signal line-drive circuit 203. When image data is inputted from the panel-control line 108 to the MEMS panel 200, the signal-input circuit 201 controls the scanning-signal line-drive circuit 201 at a predetermined timing, and the shutter open/close timing is inputted to the signal line 202. Each pixel 206 receives instruction for opening and closing from the signal line 202 at the timing that is inputted to the scanning-signal line 204. It should be noted that the present invention is not to be construed to be limited to this control configuration.

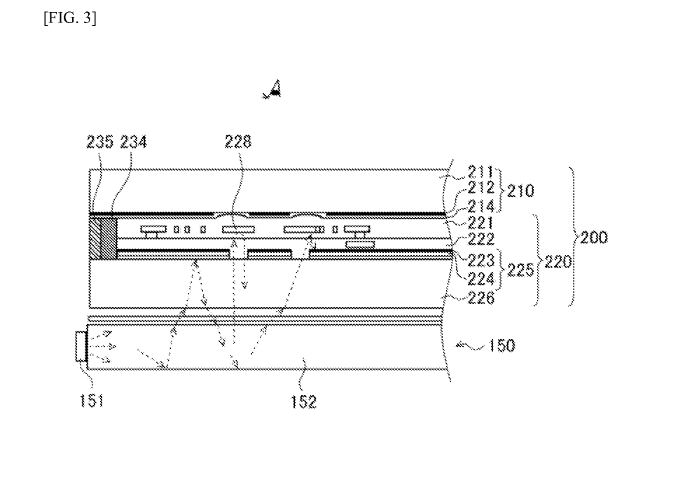

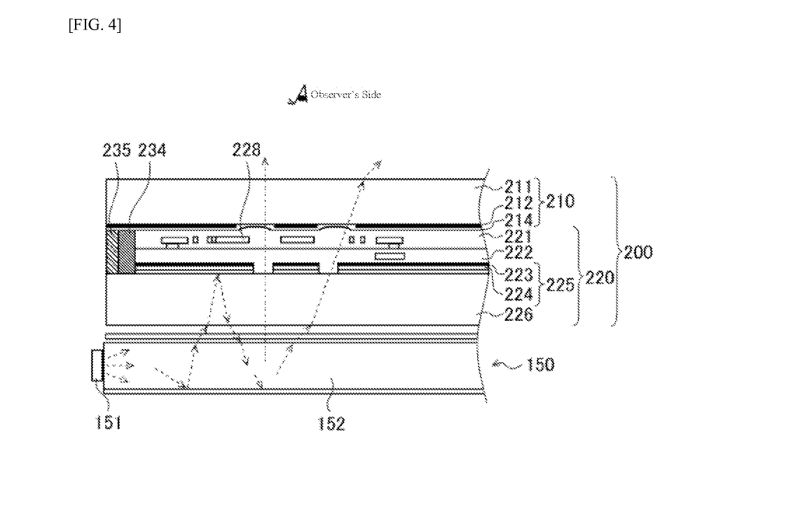

FIGS. 3 and 4 are cross-sectional views for explaining the opened state and the closed state of the shutter in the MEMS shutter display device 100.

As illustrated in FIGS. 3 and 4, the backlight 150 is composed of a light source 151 that uses an LED (Light Emitting Diode) or a similar device, and a light-guiding plate 152 that emits to the MEMS panel 200 light emitted from the light source 151 and incident from a side face. The MEMS panel 200 is composed of a MEMS shutter array 220 disposed at the backlight 150 side, and an aperture plate 210 formed disposed at an observer's side of a display device screen.

The MEMS shutter array 220 is composed of a transparent substrate 226 that is an insulating substrate, and a first aperture layer 225 formed on the transparent substrate 226, that includes an aperture (opening), a switching element layer 222 equipped with a switching element composed of a thin-film transistor and the like, and a wire connected thereto, and the MEMS shutter 228.

The aperture plate 210 includes a second aperture layer 212 formed by a light-blocking film that includes an aperture formed of a film on the transparent substrate 211, and a high refractive index layer 214 formed to cover the light-blocking film aperture. Here, the MEMS shutter array 220 and the aperture plate 210 are arranged to overlap, be sealed by a seal 234, and be filled with a transparent fluid 221 therebetween. For that reason, the MEMS shutter 228 operates in the transparent fluid 221. A fluid such as silicone oil or a similar material, or a gas such as inert gas such as nitrogen or a similar gas, or air can be used as the transparent fluid 221. A conductive unit 235 composed of conductive material is formed at an outside of the seal 234 so that there is no electrical potential difference between the MEMS shutter 228 and the second aperture layer 212.

The first aperture layer 225 has a light-reflective layer 224 whose backlight side surface has a high reflectivity; an opposite side has an anti-reflection layer 223 with a low reflectivity. The light-reflective layer 224 may be composed of a metal layer with a high reflectivity; silver (Ag), aluminum (Al) or an alloy of these can be used. If necessary, it is acceptable to dispose a reflection increasing layer composed of a multilayer dielectric film between the transparent substrate 226 and the light-reflecting layer 224. It is acceptable to use a known technique for the reflection increasing layer. For example, it is acceptable to use one that alternately stacks two types of layers, namely one having a high refractive index and one having a low refractive index. Specifically, if a light wavelength is γ and a refractive index of the layer is n, it is acceptable to stack layers with a high refractive index and a low refractive index for an optical thickness of γ/4 n. Furthermore, by increasing the number of layers, it is possible further to increase the reflectance at a predetermined wavelength. Nevertheless, considering costs and the size of a wavelength range, two or four layers are practical.

Also, it is possible to use SiOx as the low refractive index layer, and SiNx, TiO2, and Nb2O5 and others for the high refractive index layer.

The anti-reflection layer 223 can be a layer that suppresses reflection of light. For example, it is acceptable to stack metal with low reflectivity, or an inorganic material, or an organic material such as black resist and the like, on the light-reflective layer 224. It is also acceptable to form a stacked layer on the light-reflective layer 224 to suppress the reflectance by using light interference. Images are formed by opening and closing the MEMS shutter 228 that controls the passing and blocking of light through the aperture of the first aperture layer 225 from the backlight 150.

The second aperture layer 212 has a feature for increasing visibility and image quality of the display device by blocking light that passed through the MEMS shutter 228, preventing a reflecting of light incident from outside, and the like, and a feature for blocking light that entered inside from outside. For that reason, the reflectance of both faces of the second aperture layer 212, i.e., the backlight side and the observer's side, are low, as no transmittance of light is desired. It is also acceptable for a configuration composed of a stacked layer designed to suppress the reflectivity by using, for example, a black resist material or, alternatively, using metal layers with light interference therebetween; however, the present invention is not limited these examples.

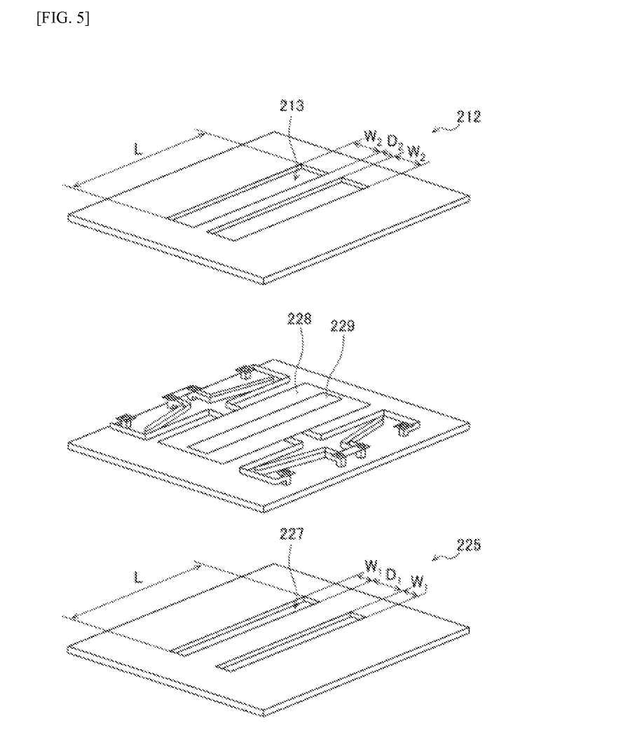

FIG. 5 is a perspective view that extracts and illustrates three layers that control transmission of light from the backlight 150 in one pixel 206 of the MEMS panel 200. Included in the MEMS panel of the present invention is an anisotropic opening whose length in a direction parallel (a short axis direction) to a movement direction of the MEMS shutter 228 on the first aperture layer 225 is short, and length in a direction (a long axis direction) orthogonal thereto is long. In this embodiment, as illustrated in the drawings, two substantially rectangular apertures 227 are arranged for one pixel in the first aperture layer 225, with an aperture width W1, in other words a length W1 in the short axis direction, and a length L in the long axis direction, leaving a space D1 empty in the width direction. Also, the MEMS shutter 228 includes at a central portion one aperture 229. Two substantially rectangular apertures 213 are arranged in the second aperture layer 212, with an aperture width W2, in other words a length W2 in the short axis direction, and a length L in the long axis direction, leaving a space D2 in the width direction.

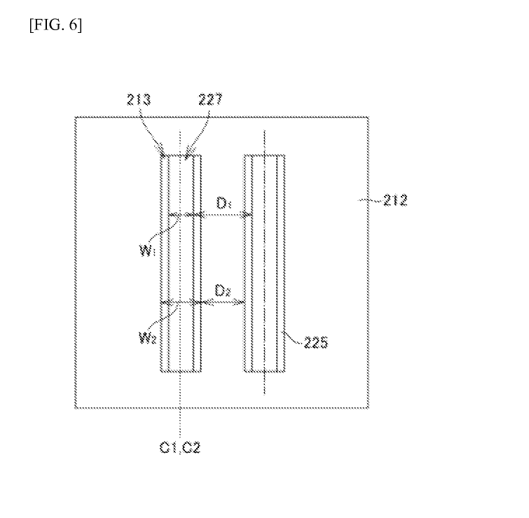

FIG. 6 is a schematic plan view illustrating from a view from a front face of a display surface an arrangement of each aperture of a first aperture layer 225 and a second aperture layer 212 in one pixel of the MEMS panel 200. As illustrated in this drawing, the width W2 in the aperture 213 of the second aperture layer 212 is larger than the width W1 of the aperture 227 of the first aperture layer 225. The reason for this is so that brightness in the front direction will not dramatically drop when the first aperture layer 225 and the second aperture layer 212 positions become misaligned, or to suppress a drop in brightness in an oblique direction in an orientation parallel to the short axis direction. Also, in this embodiment, a center axis C1 of the aperture 227 on the first aperture layer 225 and a center axis C2 of the aperture 213 in the second aperture layer 212 match, but this is not a limitation. For example, it is acceptable for the center axis C2 to be in a direction offset from a pixel center, in other words, in a direction at an edge of the pixel.

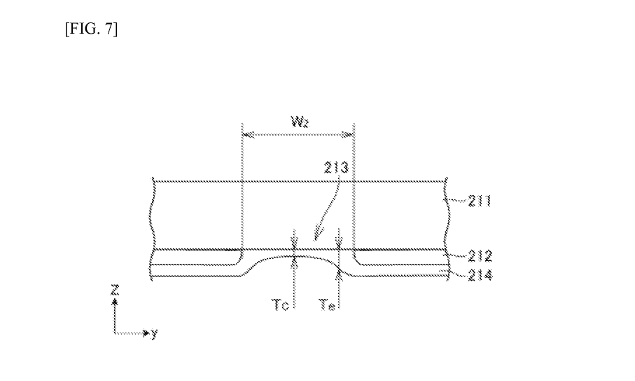

FIG. 7 is a schematic cross-sectional view near the aperture 213 of the second aperture layer 212. As described above, it is also acceptable for a configuration for the second aperture layer 212 to be composed of a stacked layer designed to suppress reflectance by using a black resist material, or a metal layer or by using light interference therebetween the metal layer. It is also acceptable to form the aperture 213 using a known processing technique such as photolithography or a similar process. The high refractive index layer 214 composed of a transparent body having a transparency of visible light of 90% or higher, has a higher refractive index than the transparent fluid 221 disposed between the first aperture layer 225 and the second aperture layer 212, and is formed on the aperture 213. A fluid such as silicone oil or a similar material, or a gas such as inert gas such as nitrogen or a similar gas, or air can be used for the transparent fluid. In either case, because it is necessary for the refractive index of the high refractive index layer 214 to be higher than the transparent fluid, it is desired that at least the silicone oil refractive index is greater than approximately 1.35. It is possible to use an organic transparent material such as an acrylic-based transparent resist or similar material, or an inorganic transparent material such as an oxide such as silicon oxide, titanium oxide, or niobium oxide, or a nitride such as silicon nitride.

When an organic material is used as the high refractive index layer 214, the layer 214 is formed using a coating process. However, it is possible to make the thickness of the high refractive index layer 214 different in the aperture 213, as illustrated in FIG. 7, by properly adjusting a viscosity of the material when implementing the coating process. Specifically, it is possible to form a thickness Tc of the high refractive index layer 214 in a center of the aperture 213 into a concave lens shape that is less than the thickness Te of the aperture edge. Particularly, compared to the long axis direction, the aperture length W2 is narrow in the short axis direction of the aperture 213, so there is wide ratio of the curved face portion having a different inclination at the surface of the high refractive index layer.

Conversely, when using an inorganic material as the high refractive index layer 214, in general, a film forming method, such as CVD (Chemical Vapor Deposition) or a sputtering method or similar method is used. However, in such a case, it is easy to form a layer following a shape of a base.

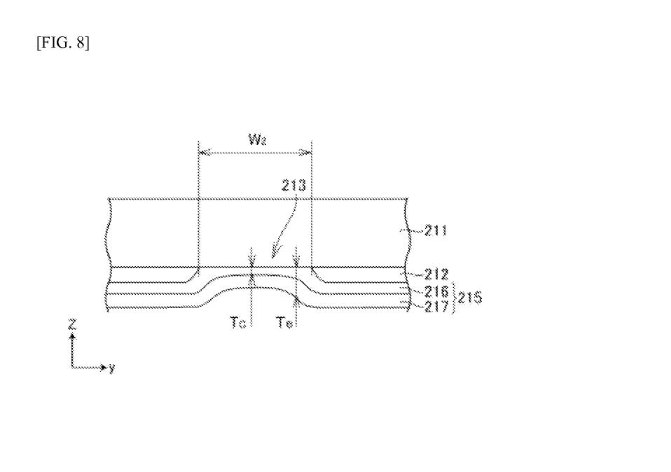

FIG. 8 is a schematic cross-sectional view of a high refractive index layer 215 that is an alternative example of a high refractive index layer 214 in FIG. 7 illustrated with a view in the same way as in FIG. 7. As depicted in the drawing, when an inorganic material is used as the high refractive index layer, it is acceptable that the thickness Tc of the high refractive index layer 215 at a center of the aperture is less than the thickness Te adjacent to an edge of the aperture, by stacking a plurality of high refractive index layers, for example the high refractive index layer 216 and the high refractive index layer 217. FIG. 8 illustrates a two-layer high refractive index layer 215 configuration. However, in such a case, it is acceptable for a first high refractive index layer 216 and a second high refractive index layer 217 to be the same material, or to be different.

For example, if the first high refractive index layer 216 is an organic material and the second high refractive index layer 217 is an inorganic material, a surface of the high refractive index layer 216 will have a curved lens shape, so it is possible for the surface shape of the second high refractive index layer 217 that is stacked thereupon also to be a curved lens shape. Conversely, it is acceptable for the thickness Tc at the center of the overall aperture in the high refractive index layer 215 to be less than the thickness Te of the aperture edge by removing only a region that corresponds to the aperture center on the first high refractive index layer 216.

Note that the high refractive index layer of the aperture may be composed of multiple layers, of three or more layers. In such a case, it is acceptable to reduce reflection at the high refractive index layer by using the interference effect. In such a case, the transmission factor of the aperture ratio is improved thereby attaining a brighter image. It should be noted that the high refractive index layer pursuant to the present invention is not to be construed to be limited to this example.

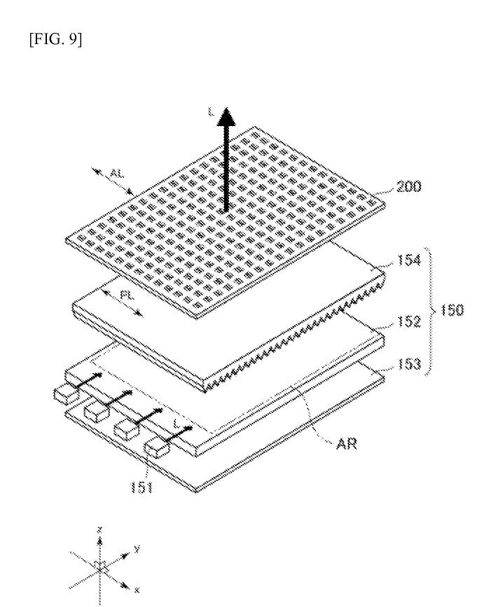

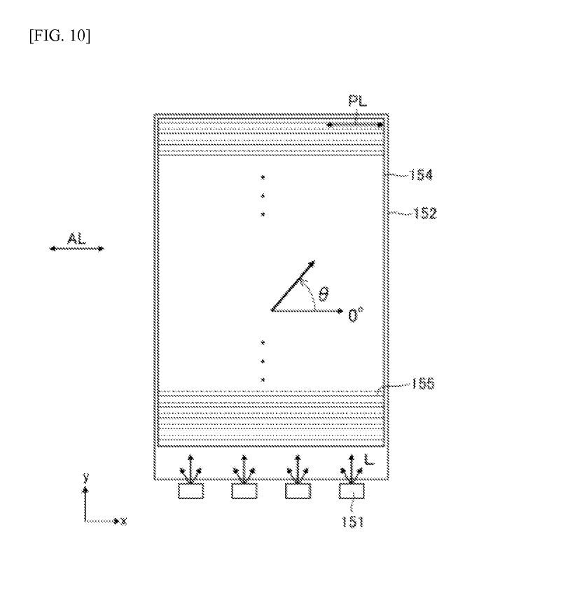

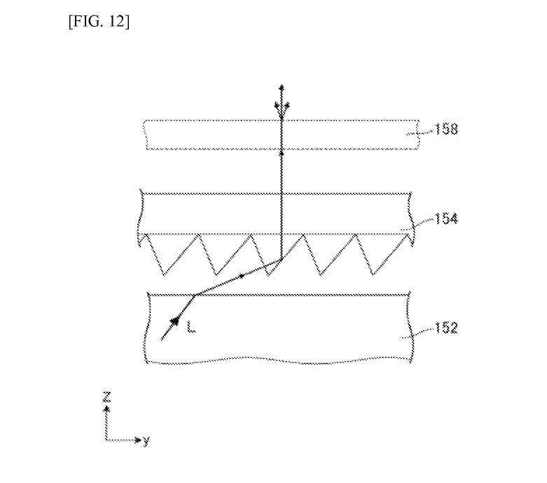

FIG. 9 is an exploded perspective view schematically illustrating a constitution of the MEMS panel 200 and the backlight 150. FIG. 10 is a schematic plan view schematically illustrating a constitution of the backlight 150. As illustrated in the drawings, the backlight 150 includes a light-guiding plate 152, a plurality of light sources 151, a reflective sheet 153, and a prism sheet 154, and if necessary, it may further be equipped with a diffusion sheet 158 (see FIG. 12) between the MEMS panel 200. The light-guiding plate 152 is a transparent plate-shaped optical unit that converts light emitted from the light source 151 into a planar illuminating light. The light-guiding plate 152 is disposed between the diffusion sheet 153 and the prism sheet 154. This is configured to reflect light emitted from the light source 151 from a region AR of a rectangular face that mainly opposes the prism sheet.

In the description below, the face that opposes the prism sheet 154 in the light-guiding plate 152 is called a top surface, or a light-emitting surface; a face that opposes the reflective sheet 153 is called a back surface. A shape of the region AR of the light-emitting surface is the same rectangular shape as the display region of the MEMS panel which is an irradiated subject. Also, as illustrated in FIG. 9, a length direction of the edge face with the light source 151 adjacently disposed, in the light-guiding plate 152 is the x direction. The direction that is perpendicular to this edge is the y direction. A light-emitting direction perpendicular to the top surface (light-emitting surface) is the z direction.

It is desired that the light source 151 satisfies the conditions of being compact, having a high luminous efficiency and low heat generation. In this way, a cold cathode fluorescent tube and a light-emitting diode (also known as LED) are examples of such a light source 151. In this embodiment, an example is given illustrating an LED being used as the light source 151. However, the present invention is not limited to this. In a case where LEDs are used for the light source 151, they can be arranged by lining up a plurality of the light sources 151 along an edge face of the light-guiding plate 152, as illustrated in FIGS. 9 and 10, because LEDs are point-type light sources. Note that the number of light sources 151 and the method of arrangement can be changed as required.

Also, to implement a color display, light-emitting diodes that emit the three primary colors of red, green, and blue is used for the light source 151. Alternatively, the light-emitting diodes that emit the three primary colors may include a light source that emits white light. Furthermore, the light source 151 is connected to a light-emitting control circuit 102 that controls the power supply and lighting and extinguishing via wiring.

The reflective sheet 153 disposed at a back surface side of the light-guiding plate 152 is effectively used by returning light emitted from the backside of the light-guiding plate 152 to the light-guiding plate 152. It is possible to use a sheet formed with a reflective layer having high reflectivity on a support base material such as a plastic plate or a polymeric film or a similar material for the reflective sheet 153. The reflective layer can be formed using a method for forming a film using a vapor-deposition technique, a sputtering method, or others that form on the support base material a thin metal film having a high reflectivity, such as aluminum, silver or other similar material, or a method that forms on the support base material multilayers of a dielectric to be a reflection increasing layer, or that coats the support base material with a coating material. Also, the reflective sheet 153 may function as reflective means by, for example, stacking a plurality of layers of a transparent medium of different refractive indices.

The prism layer 154 disposed at the top surface side of the light-guiding plate 152 is an optical sheet equipped with a feature that changes an advancing direction of light emitted from the light-emitting surface of the light-guiding plate 152. The prism sheet 154 is equipped with prism rows composed of a plurality of prisms. As illustrated in FIGS. 9 and 10, a ridge line 155 on the prism sheet 154 extends in a direction parallel to the length direction of an edge face disposed adjacent to a light source 151 of the light-guiding plate 152.

When necessary, it is acceptable to dispose the diffusion sheet 158 (see FIG. 12) at a top side of the prism sheet 154, looking from the light-guiding plate 152. The diffusion sheet 158 diffuses light that has passed through the prism sheet 154. For example, this adjusts a distribution of an emission angle of light emitted from the backlight 150 and improves uniformity of a brightness distribution in a light emitting surface of the backlight 150. The diffusion sheet 158 is disposed when required, and can be used in a known backlight. For that reason, a detailed description will be omitted.

Note that an angle of orientation θ also illustrated in FIG. 10 defines a length direction of the edge face with the light source 151 of the light-guiding plate 152 adjacently disposed as 0°, and defines as a positive angle an angle in a counterclockwise direction when viewing the light-guiding plate 152 from above the light emitting surface.

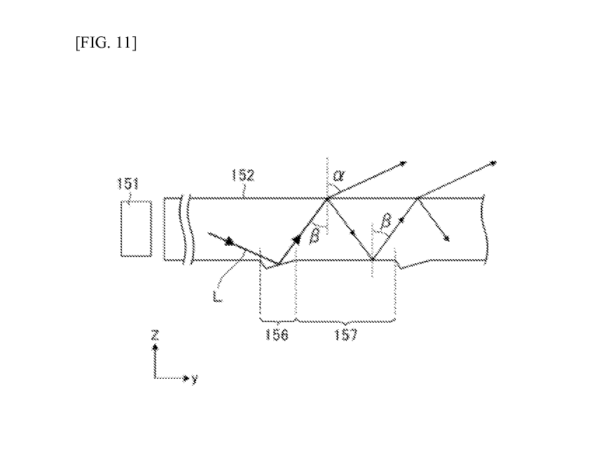

FIG. 11 is a schematic cross-sectional view illustrating one example of a cross-sectional shape of the light-guiding plate 152 in FIG. 9. Also, FIG. 11 is a cross-sectional view parallel to the yz planes in xyz coordinates illustrated in FIG. 9. It is acceptable to use a material for the light-guiding plate 152 that is transparent to visible light and has little loss of light. For example, it is acceptable to use a polyethylene terephthalate resin, a polycarbonate resin, a cyclic olefin resin or an acrylic resin or the like.

The light-guiding plate 152 waveguides light L incident from an edge face of the light source 151, emitted from the light source 151, and includes a feature for converting the light from the light source into planar light by emitting a portion from the light-emitting surface. At this time, the light-guiding plate 152 is composed of a rectangular plate member transparent with regard to visible light, and includes an oblique portion (light-extraction structure 156) for emitting light L waveguided by the light-guiding plate 152 by being incident from an edge face, from the light-emitting surface. Illustrated in FIG. 11 is a V-shaped structure equipped at the back surface of the light-guiding plate 152, as one example of the light-extraction structure.

Also, it is acceptable to use a known technique for forming the light-extraction structure 156. For example, it is possible to form on a back surface of the light-guiding plate 152 minute steps, or a concave shape or lens shape, or to implement using a structure that changes an advancing angle (an angle of incident to the top surface) of the light L waveguided by the light-guiding plate 152, such as by printing dots using a white pigment. Also, considering the cost of manufacturing the light-guiding plate 152, the efficiency and directivity of light emitted from the light-guiding plate 152, it is desired to form fine shapes that changes the advancing angle of light waveguided to the back surface of the light-guiding plate 152. It is acceptable if the fine shape is equipped with an oblique surface that can change the advancing angle of the light waveguided into the transparent material, and to implement that using a shape such as a step, concave or convex shape or a lens shape.

Light L incident to the light-guiding plate 152 is waveguided in the y axis direction mainly, while totally reflecting at the top surface and the back surface of the light source 152. At this time, when the light L is reflected by the light-extracting structure, the advancing angle β (angle of incidence to the top surface) is smaller than that before reflecting. At this time, when the advancing angle β is smaller than the critical angle, in other words the minimum angle to satisfy total reflection conditions, a portion of the light L is emitted from the light-guiding plate at an emission angle α while being refracted.

Also, as illustrated in FIG. 10, a component of the advancing direction that is not parallel to the y axis direction is included in the light L emitted from the light source 151 and incident on light-guiding plate 152. However, the major portion of light advances toward a direction of an opposing edge face from an edge face of the light-guiding plate 152 with the light source 151 adjacently disposed. In other words, the main advancing direction of the light waveguided by the light-guiding plate 152 is a direction perpendicular (the y axis direction) to the edge face of the light-guiding plate 152.

The structure of the prism sheet 154 pursuant to the present invention will now be described. FIG. 12 is a schematic cross-sectional view illustrating one example of an overall configuration of the prism sheet 154 in the backlight 150 in FIG. 9. This illustrates a section parallel to the yz planes at the xyz coordinates illustrated in FIG. 9. In other words, this illustrates a cross-sectional configuration at a section parallel to the main advancing direction of the light waveguided by the light-guiding plate 152. As illustrated in FIG. 12, the prism sheet 154 using a transparent film as a base material and forming a prism in a matrix on a surface thereof is realistic when considering utility in industry, such as in manufacturing and the like. However, the present invention is not limited to this structure or manufacturing method of the prism sheet 154. For example, it is acceptable for the base portion and the prism portion to be an inseparable integrated shape. For the transparent film used as the base material, it is possible, for example, to use a polyethylene terephthalate film, a triacetylcellulose film, or a polycarbonate film.

The prism sheet 154 pursuant to this embodiment uses a prism matrix at the light-guiding plate 152 side. This prism matrix acts to change a direction of the light L emitted from the light-guiding plate 152 substantially to a front face direction by total reflection at oblique faces relatively at a far side from the light source 151, looking from an apex of the prism.

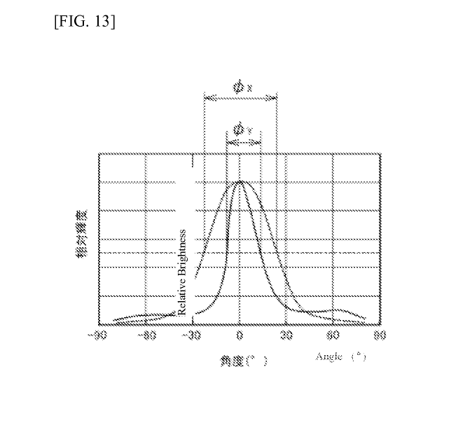

With the backlight 150 used in this kind of structure, directivity of the emitted light varies according to the orientation angle. FIG. 13 is a graph showing one example of the relationship (brightness view angle characteristics) of brightness of the backlight 150 and the view angle. As shown in the graph, the half-value angle Ø of brightness is in a direction perpendicular to the direction PL of the prism ridge line of the prism sheet 154. In other words, the half-value angle Øy of the y axis direction is narrower than the half-value angle Øx of the x axis direction. In this embodiment, as illustrated in FIGS. 9, 10, and the like, the long axis direction AL of the aperture in the MEMS panel 200 and the prism ridge line direction PL in the prism sheet 154 in the backlight 150 are substantially conincident. Said another way, the short axis direction of the aperture in the MEMS panel 200, and the prism ridge line direction PL in the prism sheet 154 in the backlight 150 are arranged to be substantially perpendicular. By using such a structure, the light with a narrow view angle of the brightness, that is, a narrow half angle Ø of the brightness, and with strong directivity is made to be incident in an orientation parallel to the short axis direction of the aperture.

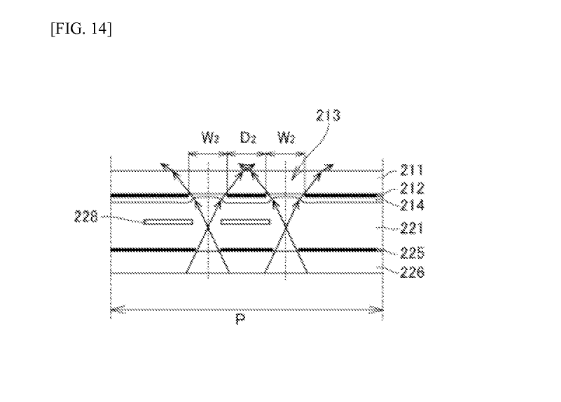

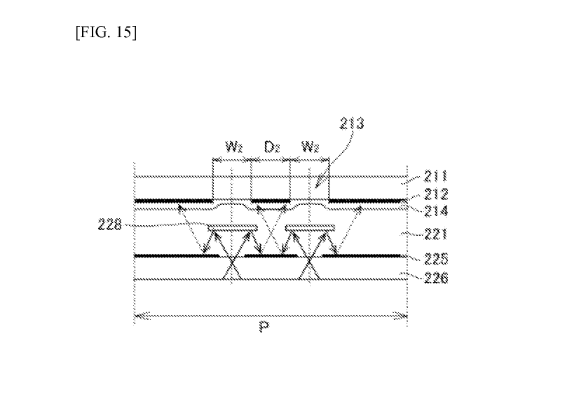

FIGS. 14 and 15 are views to describe a status of light when the shutter is opened and when the shutter is closed, illustrating a schematic cross-sectional structure of the MEMS panel 200. With the shutter in an open state in FIG. 14, the advancing direction of a portion of the light that passes through the aperture in the first aperture layer 225 is changed by the high refractive index layer 214 disposed in the aperture, when that light passes through the second aperture layer 212, thereby expanding the view angle of the brightness. At that time, by using the backlight 150 of the configuration described above, light emitted from the backlight 150 takes on stronger directivity in the short axis direction of the aperture. For that reason, if the conventional backlight (a backlight without a narrow half-value angle for brightness in the short axis direction of the aperture) is used, the portion of the light equivalent to the light that is lost by being blocked at the second aperture layer 212 passes through the aperture 213 of the second aperture layer 212. Therefore, the transmission factor of light emitted from the backlight at the MEMS panel 200 is increased, thereby improving the brightness in the oblique direction of the display device for the amount of increase in the transmission factor.

Also, with the closed state of the shutter depicted in FIG. 15, if the conventional backlight (a backlight without a narrow half-value angle for brightness in the short axis direction of the aperture) is used, the portion of the light reflected by the MEMS shutter 228 of the light that passes through the aperture of the first aperture layer 225 leaks from the adjacent aperture 213 of the second aperture layer 212. In contrast, when the backlight 150 with this configuration is used, the light emitted from the backlight 150 becomes light with stronger directivity in the short axis direction of the aperture 213 so a majority of the light reflected by the MEMS shutter 228 is blocked by the second aperture layer 212. Therefore, light leaks in the oblique direction when displaying black (darkness) are suppressed. Specifically, with the display device pursuant to the present invention, brightness of bright displays in the oblique direction is improved, and black (dark) displays are darker, thereby improving a contrast ratio, in the orientation parallel to the short axis direction of the aperture in the first and second aperture layers.

As described above, pursuant to the display device of this embodiment of the present invention, the brightness in oblique directions is increased in an orientation parallel to the short axis direction in the conventional aperture with a narrow view angle. Also, the contrast ratio is improved because light leaks are reduced when block is displayed in the same orientation. Specifically, the view angle is wider in the orientation parallel to the short axis direction of the aperture. For that reason, a display device with a smaller dependency on the orientation angle of the view angle is attained.

### Second Embodiment

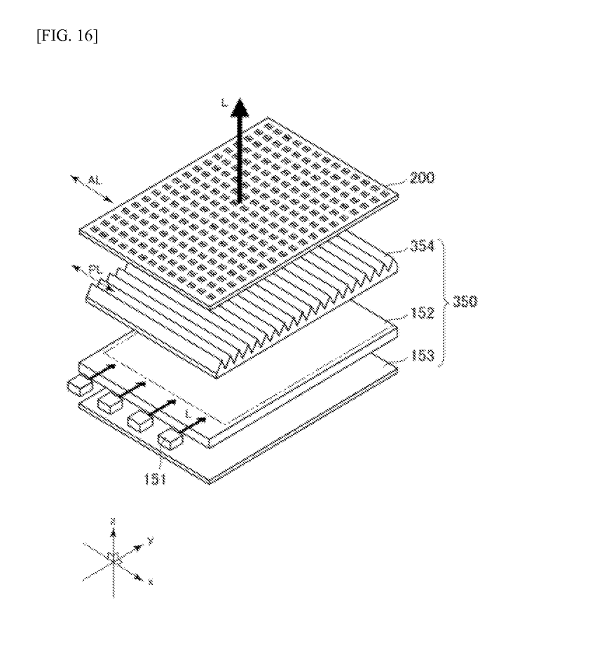

FIG. 16 is an exploded perspective view schematically illustrating the MEMS panel 200 and the backlight 350 in a MEMS shutter display device, pursuant to a display device of the second embodiment of the present invention. The configuration of the MEMS shutter display device in this embodiment changes the configuration of the backlight 150 of the first embodiment to a backlight 350. Descriptions of other configuring portions are the same as those in the first embodiment, and therefore will be omitted. The backlight 350 is different from the prism sheet 154 in the first embodiment in that the prism matrix in the prism sheet 354 is disposed at the MEMS panel 200 side.

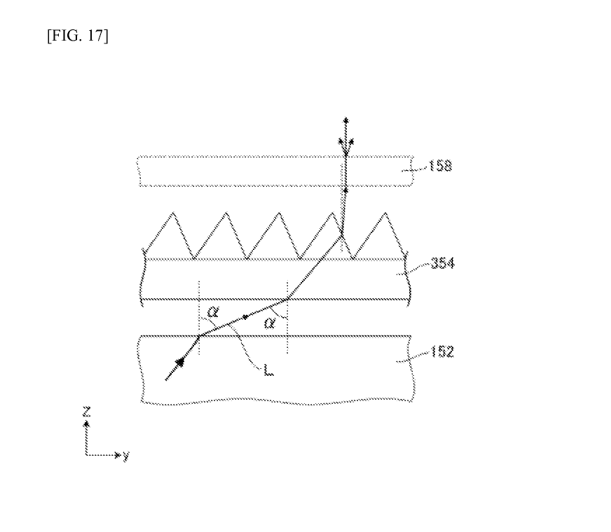

FIG. 17 is a schematic section illustrating one example of a schematic configuration of the prism sheet 354 in the backlight 350 in FIG. 16. This illustrates a section parallel to the yz planes at the xyz coordinates illustrated in FIG. 16. In other words, this illustrates a cross-sectional configuration at a section parallel to the main advancing direction of the light waveguided by the light-guiding plate.

As illustrated in FIG. 17, the prism sheet 354 uses a transparent film as a base material, and forms a prism on a surface thereof into a matrix, which is realistic when considering utility in industry, such as in manufacturing and the like. However, the present invention is not limited to this structure or manufacturing method of the prism sheet 354. For example, it is acceptable for the base portion and the prism portion to be an inseparable integrated shape. For the transparent film used as the base material, it is possible, for example, to use a polyethylene terephthalate film, a triacetylcellulose film, or a polycarbonate film.

The prism sheet 354 uses a prism matrix at the light-guiding plate 200 side. This prism matrix acts to direct the light L emitted from the light-guiding plate 152 substantially to a front face direction by refraction at oblique faces at a far side from the light source, looking from an apex of the prism.

With the backlight 350 of such a structure, directivity of the emitted light varies according to the orientation angle. Specifically, a half-value angle of brightness is in a direction perpendicular to the direction PL of the prism ridge line of the prism sheet 354, in other words, the y axis direction is narrower than the x axis direction. In this embodiment, the long axis direction AL of the aperture 213 in the MEMS panel 200, and the prism ridge line direction PL in the prism sheet 354 in the backlight 350 are substantially equal, as illustrated in FIG. 16. Said another way, the short axis direction of the aperture 213 in the MEMS panel 200, and the prism ridge line direction PL in the prism sheet 354 in the backlight 350 are arranged to be substantially perpendicular. By using such a structure, the light with a narrow view angle of the brightness, that is, the narrow half angle Ø of the brightness, and with strong directivity is made to be incident in the orientation parallel to the short axis direction of the aperture 213. In such a case, with the shutter in an open state, the advancing direction of a portion of the light that passes through the aperture in the first aperture layer 225 is changed by the high refractive index layer 214 disposed in the aperture, when that light passes through the second aperture layer 212, thereby expanding the view angle of the brightness. At that time, because the light emitted from the backlight 350 takes on stronger directivity in the short axis direction of the aperture, in the conventional backlight (a backlight without a narrow half-value angle for brightness in the short axis direction of the aperture), the portion of the light equivalent to the light that is lost by being blocked at the second aperture layer 212 passes through the aperture 213 of the second aperture layer 212 by using the backlight 350 described above. Therefore, the transmission factor of the MEMS panel is increased, thereby improving the brightness in the oblique direction of the display device.

Also, with the closed state of the shutter, if the conventional backlight (a backlight without a narrow half-value angle for brightness in the short axis direction of the aperture) is used, of the light that passes through the aperture 227 of the first aperture layer 225, light is leaked from the adjacent aperture 213 of the second aperture layer 212 by being reflected by the shutter. Conversely, when the backlight 350 described above is used, light emitted from the backlight 350 takes on stronger directivity in the short axis direction of the aperture so it is blocked by the second aperture layer 212. For that reason, light leaks in the oblique direction when displaying black are suppressed. Specifically, in this embodiment, the brightness of bright displays in the oblique direction is improved, and black (dark) displays are darker, thereby improving a contrast ratio, in the orientation parallel to the short axis direction of the aperture in the first and second aperture layers. In other words, the view angle is wider in the orientation parallel to the short axis direction of the aperture. A display device with a smaller dependency on the orientation angle of the view angle is attained.

### Third Embodiment

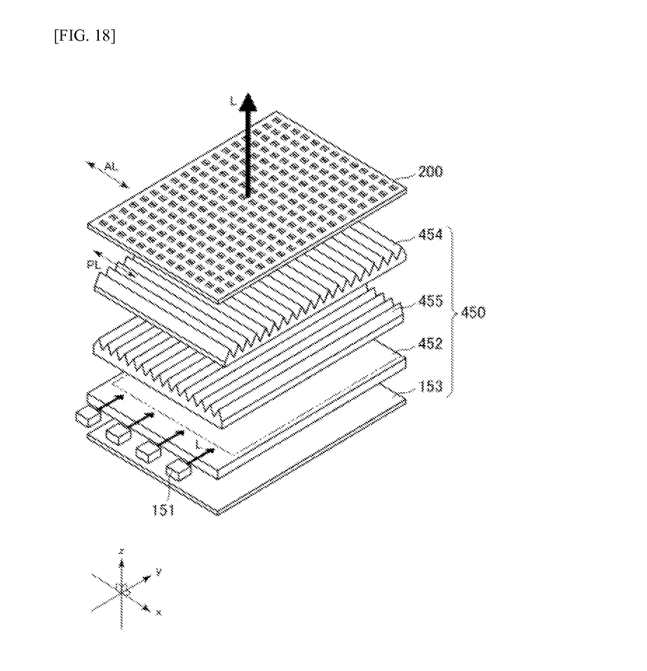

FIG. 18 is an exploded perspective view schematically illustrating a constitution of the MEMS panel 200 and the backlight 450 in the MEMS shutter display device, pursuant to a display device of the third embodiment of the present invention. The constitution of the MEMS shutter display device in this embodiment changes the configuration of the backlight 150 of the first embodiment to a backlight 450. Descriptions of other configuring portions are the same as those in the first embodiment, and therefore will be omitted. The backlight 450 includes the light-guiding plate 452, a plurality of light sources 151, the reflective sheet 153, two prism sheets 454 and 455, and if necessary, may further be equipped with the diffusion sheet 158 disposed between the MEMS panel 200 and the prism sheet 454. This embodiment particularly differs from the first embodiment in that two prism sheets are disposed at a top surface of a light-guiding plate 452. Furthermore, the prism matrix of two prisms 454 and 455 is disposed at the MEMS panel 200 side.

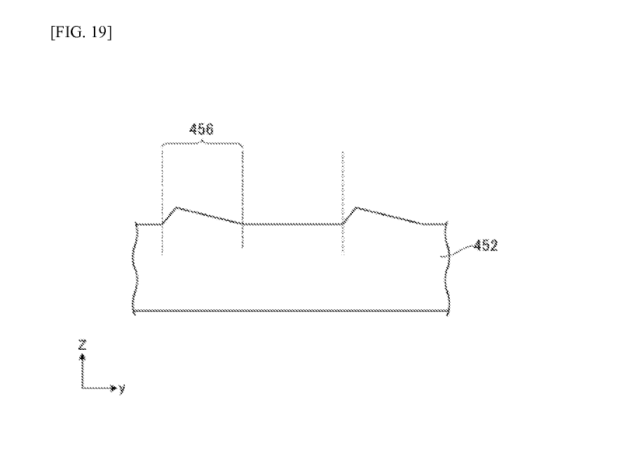

FIG. 19 is a schematic section illustrating one example of a cross-sectional configuration of the light-guiding plate 452 in the backlight 450. Also, FIG. 19 is a cross-sectional configuration seen from a section parallel to the yz planes in xyz coordinates illustrated in FIG. 18. The drawing illustrates a configuration seen in a depth direction of the section. It is acceptable to use a material for the light-guiding plate 452 that is transparent to visible light and has little loss of light. For example, it is acceptable to use a polyethylene terephthalate resin, a polycarbonate resin, a cyclic olefin resin or an acrylic resin or the like.

The light-guiding plate 452 waveguides light L incident from an edge face at one side, emitted from the light source 151, and includes a feature for converting the light L into planar light by emitting a portion from the top surface. At this time, the light-guiding plate 452 is composed of a transparent rectangular shaped plate member, for visible light, and includes an oblique portion (light-extraction structure 456) for emitting light waveguided by the light-guiding plate 452 from the light-emitting surface by being incident from an edge face. The light-extraction structure 456 may be the light-extraction structure 156 equipped to a back surface side like the light-guiding plate 152 in the first embodiment, but as illustrated in FIG. 19, it may also be a V-shaped light-extraction structure 456 equipped at a top surface of the light-guiding plate 452.

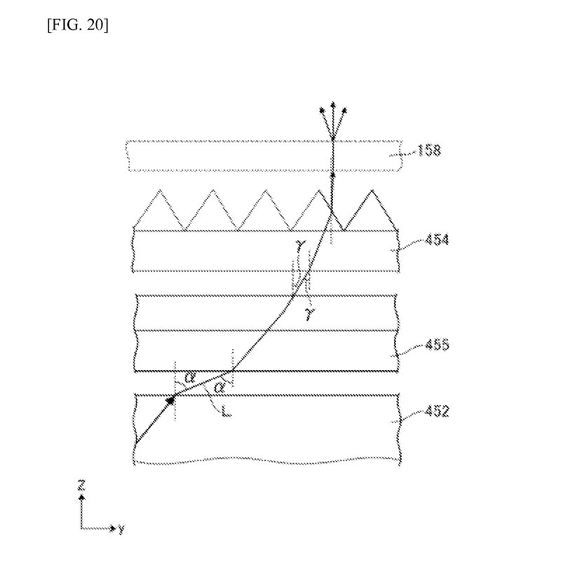

FIG. 20 is a schematic cross-sectional view illustrating one example of a schematic configuration of the prism sheets 454 and 455 in the backlight 450 illustrated in FIG. 18. This illustrates a section parallel to the yz planes at the xyz coordinates illustrated in FIG. 18. In other words, this illustrates a cross-sectional configuration at a section parallel to the main advancing direction of the light waveguided by the light-guiding plate.

The prism sheets 454 and 455 of this embodiment use a transparent film as a base material, as illustrated in FIG. 20, and forms the prisms on a surface thereof into a matrix, which is realistic when considering utility in industry, such as in manufacturing and the like. However, the prism sheets 454 and 455 are not limited to this structure or manufacturing method. For example, it is acceptable for the base portions and the prism portions to be inseparable integrated shape. For the transparent film used as the base material, it is possible, for example, to use a polyethylene terephthalate film, a triacetylcellulose film, or a polycarbonate film.

Of the two prism sheets 454 and 455, the prism sheet 455 disposed at the light-guiding plate side is disposed so that the prism ridge line direction PL is substantially parallel (θ=approximately 90°) to the y axis direction. Also, of the two prism sheets 454 and 455, the prism sheet 454 disposed at the MEMS panel side is disposed so that the prism ridge line direction PL is substantially parallel (θ=approximately 0°) to the x axis direction. With the backlight 450 of such a structure, directivity of the emitted light varies according to the orientation angle. Specifically, a half-value angle of brightness is a direction perpendicular to the direction PL of the prism ridge line of the prism sheet 454 disposed at the MEMS panel 200 side, in other words, the y axis direction is narrower than the x axis direction. In this embodiment, the long axis direction AL of the aperture in the MEMS panel 200, and the prism ridge line direction PL in the prism sheet 454 disposed at the MEMS panel 200 side are substantially equal, as illustrated in FIG. 18. Said another way, the short axis direction of the aperture in the MEMS panel 200, and the prism ridge line direction PL in the prism sheet 454 disposed at the MEMS panel 200 side are arranged to be substantially perpendicular. By using such a structure, the light with a narrow view angle of the brightness, that is, the narrow half angle Ø of the brightness, and with strong directivity is made to be incident in the orientation parallel to the short axis direction of the aperture. In such a case, with the shutter in an open state, the advancing direction of a portion of the light that passes through the aperture in the first aperture layer 225 is changed by the high refractive index layer 214 disposed in the aperture, when that light passes through the second aperture layer 212, thereby expanding the view angle of the brightness. At that time, light emitted from the backlight 450 becomes light with stronger directivity in the short axis direction of the aperture by using the backlight 450 described above. For that reason, if the conventional backlight (a backlight without a narrow half-value angle for brightness in the short axis direction of the aperture) is used, the portion of the light equivalent to the light that is lost by being blocked by the second aperture layer 212 passes through the aperture 213 of the second aperture layer 212. Therefore, the transmission factor of the MEMS panel is increased, thereby improving the brightness in the oblique direction of the display device.

Also, with the closed state of the shutter, if the conventional backlight (a backlight without a narrow half-value angle for brightness in the short axis direction of the aperture) is used, of the light that passes through the aperture of the first aperture layer 225, a portion of the light that is leaked from the adjacent aperture 213 of the second aperture layer 212 becomes light with stronger directivity in the short axis direction of the aperture because the backlight 450 is used, so it can be blocked by the second aperture layer 212. For that reason, light leaks in the oblique direction when displaying black are suppressed. Specifically, in this embodiment, the brightness of bright displays in the oblique direction is improved, and black (dark) displays are darker, thereby improving a contrast ratio, in the orientation parallel to the short axis direction of the aperture in the first and second aperture layers. In other words, the view angle is wider in the orientation parallel to the short axis direction of the aperture. A display device with a smaller dependency on the orientation angle of the view angle is attained.

### Fourth Embodiment

From the first to the third embodiment, the MEMS shutter array 220 is disposed at the backlight side, and the aperture plate 210 is disposed at an opposite side to the backlight of the MEMS shutter array 220. However, these are not limited to the configuration described above. It is also acceptable for a configuration that reverses the vertical relationship of the MEMS shutter array and the aperture plate 210, in other words, the aperture plate 210 is disposed at the backlight side.

Even in a configuration where the aperture plate 210 is disposed at the backlight side, and the MEMS shutter array 220 is disposed at an opposite side to the backlight of the aperture array 210, the same effects as the first to the third embodiments can be attained.

### EXPLANATION OF REFERENCE NUMERALS

100 MEMS shutter display device, 102 Light-emission control circuit, 104 System-control circuit, 106 Display-control circuit, 108 Panel-control line, 150 Backlight, 151 Light source, 152 Light-guide plate, 153 Reflective sheet, 154 Prism sheet, 155 Prism ridge line, 156 Light-extraction structure, 158 Diffusion sheet, 200 MEMS panel, 201 Signal-input circuit, 202 Signal line, 203 Scanning-signal line-drive circuit, 204 Scanning-signal line, 206 Pixel, 210 Aperture plate, 211 Transparent substrate, 212 Aperture, 213 Aperture, 214 High refractive index layer, 215 High refractive index layer, 216 First high refractive index layer, 217 Second high refractive index layer, 220 MEMS shutter array, 221 MEMS shutter layer, 222 Thin-film transistor layer, 223 Anti-reflection layer, 224 Light-reflective layer, 226 Transparent substrate, 227 Aperture, 228 MEMS shutter, 229 Aperture, 234 Seal, 235 Conductive unit, 350 Backlight, 354 Prism sheet, 450 Backlight, 452 Light-guide plate, 454 Prism sheet, 455 Prism sheet, 456 Light-extraction structure.

1. A display device, comprising:
a backlight that emits a planar light; and
a display panel that displays an image by controlling light emitted from the backlight using a microelectromechanical system shutter (MEMS shutter) provided in each pixel; wherein
one pixel has a first aperture layer having at least one opening with an anisotropic shape whose length in a direction substantially parallel to a movement direction of the MEMS shutter is short and whose length in a direction orthogonal thereto is long and
a second aperture layer provided with at least one opening, which is disposed to correspond to the opening of the first aperture layer, with the anisotropic shape whose length in the direction substantially parallel to the movement direction of the MEMS shutter is short and whose length in the direction orthogonal thereto is long;
in the one pixel, the MEMS shutter is provided between the first aperture layer and the second aperture layer and controls (switches) transmission and blocking of light passing through the first aperture layer by being electrically driven by a switching element;
a space between the first aperture layer and the second aperture layer in which the MEMS shutter is provided is filled with a transparent fluid;
a high refractive index layer, which is a transparent layer having a higher refractive index than the transparent fluid, is provided in the opening of the second aperture layer; and
a thickness of the high refractive index layer in a central portion of the opening of the second aperture layer is less than a thickness at an edge portion of the opening of the second aperture layer.

2. The display device according to claim 1, wherein the openings of the first aperture layer and the second aperture layer are both rectangular.

3. The display device according to claim 1, wherein the openings of the first aperture layer and the second aperture layer are both two or more in number.

4. The display device according to any of claims 1 to 3, wherein
the high refractive index layer is configured of
a first high refractive index layer configured of an organic material formed on the second aperture layer and
a second high refractive index layer configured of an inorganic material formed on the first high refractive index layer.

5. The display device according to any of claims 1 to 4, wherein
the high refractive index layer is formed of a material selected from among silicon oxide, titanium oxide, niobium oxide, or silicon nitride.

6. The display device according to any of claims 1 to 5, wherein
when a direction that is substantially parallel to the movement direction of the MEMS shutter and in which a length of an opening shape of the first and the second apertures is short is defined as a short axis direction, and when a direction that is orthogonal thereto and in which the length is long is defined as a long axis direction,
a half-value angle in the short axis direction is smaller than a half-value angle of the long axis direction for the intensity of light emitted from the backlight.

7. The display device according to any of claims 1 to 6, wherein
the backlight has a prism sheet having a ridge line that extends in the long axis direction of the openings of the first and the second aperture layers.
